(19) United States
(12) Patent Application Publication
(10) Pub. No.: US 2023/0345696 A1
(43) Pub. Date: Oct. 26, 2023

(54) METHOD OF MANUFACTURING SEMICONDUCTOR DEVICE

(71) Applicant: SAMSUNG ELECTRONICS CO., LTD., Suwon-Si (KR)

(72) Inventors: Seokhan Park, Suwon-sl (KR); Bowon Yoo, Suwon-si (KR); Hyunseo Shin, Suwon-si (KR); Kiseok Lee, Suwon-si (KR); Moonyoung Jeong, Suwon-si (KR)

(21) Appl. No.: 18/132,198

(22) Filed: Apr. 7, 2023

(30) Foreign Application Priority Data
Apr. 22, 2022 (KR) 10-2022-0050075

(51) Int. Cl. H10B 12/00

(52) U.S. Cl. CPC H10B 12/0387; H10B 12/0383; H10B 12/488

(57) ABSTRACT

A method of manufacturing a semiconductor device includes forming a plurality of first trenches in a substrate. A plurality of first filling layers is formed that fills the first trenches and have protrusions extending to protrude from the substrate. Spacers are formed on sidewalls of the protrusions of the first filling layers. The spacers expose portions of the substrate between adjacent first filling layers. A plurality of second trenches is formed around the first trenches by etching the portions of the substrate exposed by the spacers. A plurality of second filling layers is formed that fills the second trenches. All of the first filling layers and the spacers are removed. A gate material layer is formed that conformally covers inner walls of the first trenches. A pair of gate structures is formed in each of the first trenches by separating the gate material layer.

### CROSS-REFERENCE TO RELATED APPLICATION

This application claims priority under 35 U.S.C. §119 to Korean Patent Application No. 10-2022-0050075, filed on Apr. 22, 2022 in the Korean Intellectual Property Office, the disclosure of which is incorporated by reference in its entirety herein.

### 1. Technical Field

The present inventive concept relates to a method of manufacturing a semiconductor device, and more particularly, to a method of manufacturing a semiconductor device by using self-alignment.

### 2. Discussion of Related Art

High-capacity data processing is required for manufacturing semiconductor devices with smaller sizes. Therefore, it is necessary to increase the degree of integration of such semiconductor devices, and patterns formed on the semiconductor devices need to be miniaturized. Accordingly, research concerning a fine pattern having fine widths and spacings that exceed the resolution limit of a photolithography process is being conducted.

### SUMMARY

Embodiments of the present inventive concept provide a semiconductor device in which trenches formed in a later process are self-aligned with previously formed trenches, thereby preventing misalignment and increasing the reliability of the semiconductor device.

In addition, the technical goals to be achieved by embodiments of the present inventive concept are not limited to the technical goals mentioned above, and other technical goals may be clearly understood by one of ordinary skill in the art from the following descriptions.

According to an embodiment of the inventive concept, a method of manufacturing a semiconductor device, the method includes forming a plurality of first trenches in a substrate. The plurality of first trenches is spaced apart from each other in a first horizontal direction and each of the plurality of first trenches extends in a second horizontal direction orthogonal to the first horizontal direction. A plurality of first filling layers is formed that fills the plurality of first trenches. Each of the plurality of first filling layers has protrusions extending to protrude from the substrate. Spacers are formed on sidewalls of the protrusions of the plurality of first filling layers. The spacers expose portions of the substrate between adjacent first filling layers of the plurality of first filling layers. A plurality of second trenches is formed around the plurality of first trenches by etching the portions of the substrate exposed by the spacers. A plurality of second filling layers is formed that fills the plurality of second trenches and has top surfaces positioned at a same level as a top surface of the substrate. All of the plurality of first filling layers and the spacers are removed. A gate material layer is formed conformally covering inner walls of the plurality of first trenches. A pair of gate structures is formed in each of the plurality of first trenches by separating the gate material layer. A third filling layer is formed between the pair of gate structures in each of the plurality of first trenches.

According to an embodiment of the present inventive concept, a method of manufacturing a semiconductor device includes forming a plurality of first trenches in a substrate. The plurality of first trenches is spaced apart from each other in a first horizontal direction and each of the plurality of first trenches extends in a second horizontal direction orthogonal to the first horizontal direction. A plurality of first filling layers is formed that fills the plurality of first trenches. Each of the plurality of first filling layers has protrusions extending to protrude from the substrate. Spacers are formed on sidewalls of the protrusions of the plurality of first filling layers. The spacers expose portions of the substrate between adjacent first filling layers of the plurality of first filling layers. A plurality of second trenches is formed around the plurality of first trenches by etching the portions of the substrate exposed by the spacers. A plurality of second filling layers is formed that fills the plurality of second trenches and has top surfaces positioned at a same level as a top surface of the substrate. All of the plurality of first filling layers and the spacers are removed. A sacrificial material layer is formed that conformally covers inner walls of the plurality of first trenches. Portions of the sacrificial material layer are removed and separated from the plurality of first trenches to expose portions of a bottom surface of the plurality of first trenches. A plurality of third filling layers is formed that fills the plurality of first trenches and directly contacts the exposed portions of the bottom surfaces of the plurality of first trenches and sidewalls of the sacrificial material layer. The sacrificial material layer is completely removed. A pair of gate structures is formed in an empty space defined by the plurality of third filling layers in each of the plurality of first trenches.

According to an embodiment of the present inventive concept, a method of manufacturing a semiconductor device includes forming a mask layer having a plurality of openings on a substrate. A plurality of first trenches is formed by etching the substrate using the mask layer as an etching mask. The plurality of first trenches is spaced apart from each other in a first horizontal direction and each of the plurality of first trenches extends in a second horizontal direction orthogonal to the first horizontal direction. The mask layer is removed. A plurality of sacrificial layers is formed that fills the plurality of first trenches. An upper portion of the substrate is removed by a first thickness, such that portions of the plurality of sacrificial layers protrude from the substrate. Spacers are formed on sidewalls of protruding portions of the plurality of sacrificial layers. The spacers expose portions of the substrate between adjacent sacrificial layers of the plurality of sacrificial layers. A plurality of second trenches is formed around the plurality of first trenches by etching the portions of the substrate exposed by the spacers. A plurality of device isolation layers is formed that fill the plurality of second trenches and have top surfaces positioned at a same level as a top surface of the substrate. All of the plurality of sacrificial layers and the spacers are removed. A gate material layer is formed conformally covering inner walls of the plurality of first trenches. A pair of gate structures is formed in each of the plurality of first trenches by separating the gate material layer. An epitaxial growth layer is formed between the pair of gate structures in each of the plurality of first trenches.

### BRIEF DESCRIPTION OF THE DRAWINGS

Embodiments of the present inventive concept will be more clearly understood from the following detailed description taken in conjunction with the accompanying drawings in which:

FIG. 1 is a block diagram showing a method of manufacturing a semiconductor device according to an embodiment of the present inventive concept;

FIG. 2 is a layout diagram showing main components of a cell region of a semiconductor device according to an embodiment of the present inventive concept;

FIGS. 3A to 3U are cross-sectional views taken along line X-X′ of FIG. 2 showing a method of manufacturing a semiconductor device according to embodiments of the present inventive concept;

FIG. 4 is a block diagram showing a method of manufacturing a semiconductor device according to an embodiment of the present inventive concept;

FIGS. 5A to 5K are cross-sectional views taken along line X-X′ of FIG. 2 showing a method of manufacturing a semiconductor device according to embodiments of the present inventive concept;

FIG. 6 is a layout diagram showing main components of a cell region of a semiconductor device according to an embodiment of the present inventive concept;

FIG. 7 is a cross-sectional view of a cross-sectional configuration taken along a line X-X′ of FIG. 6 according to an embodiment of the present inventive concept;

FIG. 8 is a layout diagram showing a semiconductor device according to an embodiment;

FIG. 9 is a cross-sectional view of a configuration taken along lines X-X′ and Y-Y′ of FIG. 8 according to an embodiment of the present inventive concept.

### DETAILED DESCRIPTION OF EMBODIMENTS

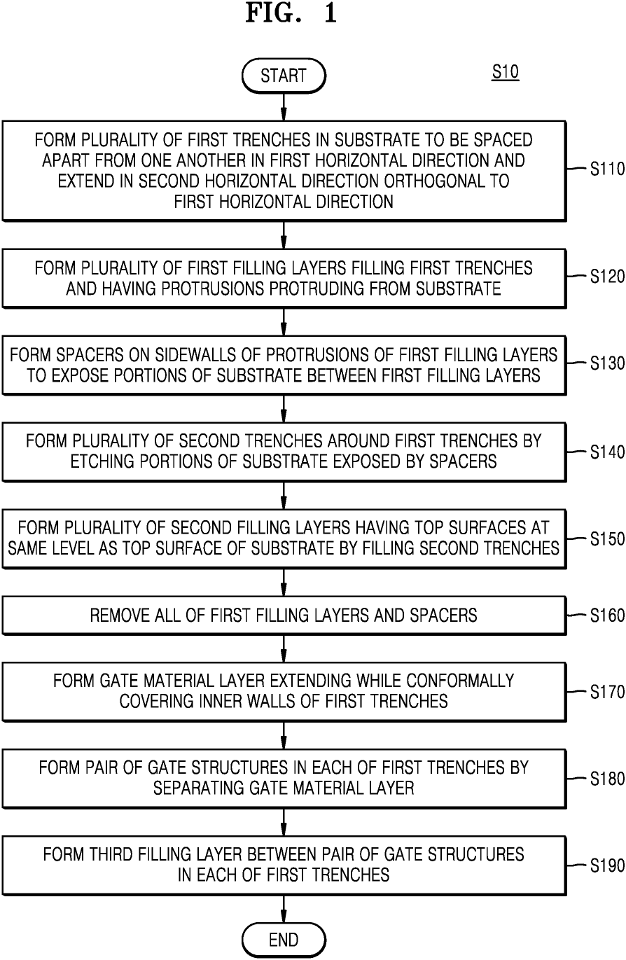

FIG. 1 is a block diagram showing a method of manufacturing a semiconductor device according to an embodiment.

Referring to FIG. 1, a method S10 of manufacturing a semiconductor device may include operations S110 to S190.

In some embodiments in which a certain operation is implemented in a different manner from FIG. 1, particular operations may be performed in an order different from that described below. For example, two successively described operations may be performed substantially simultaneously or may be performed in an order opposite to the order described below. However, embodiments of the present inventive concept are not necessarily limited thereto.

The method S10 of manufacturing a semiconductor device according to an embodiment of the present inventive concept may include a first operation S110 for forming a plurality of first trenches that are spaced apart from one another in a first horizontal direction in a substrate and extending in a second horizontal direction orthogonal to the first horizontal direction, a second operation S120 for forming a plurality of first filling layers that fill the first trenches and having protrusions extending to protrude from the substrate, a third operation S130 for forming spacers on sidewalls of the protrusions of the first filling layers that expose portions of substrate between first filling layers, a fourth operation S140 for forming a plurality of second trenches around the first trenches by etching portions of the substrate exposed by the spacers, a fifth operation S150 for forming a plurality of second filling layers having top surfaces at the same level as that of the top surface of the substrate by filling the second trenches, a sixth operation S160 for removing all of the first filling layers and the spacers, a seventh operation S170 for forming a gate material layer extending while conformally covering the inner walls of the first trenches, an eighth operation S180 for forming a pair of gate structures in each of the first trenches by separating the gate material layer, and a ninth operation S190 for forming a third filling layer between the pair of gate structures in each of the first trenches.

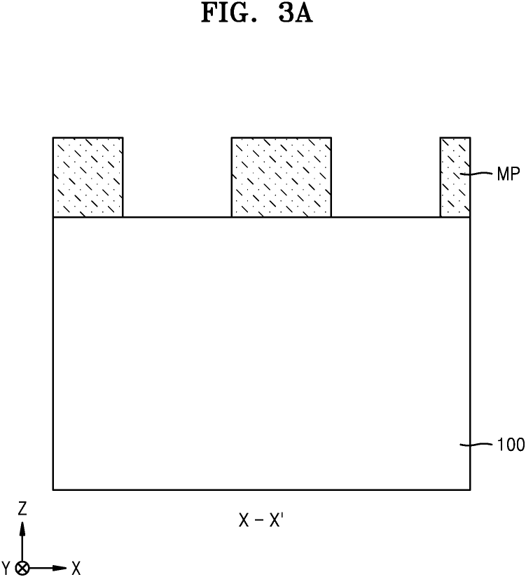

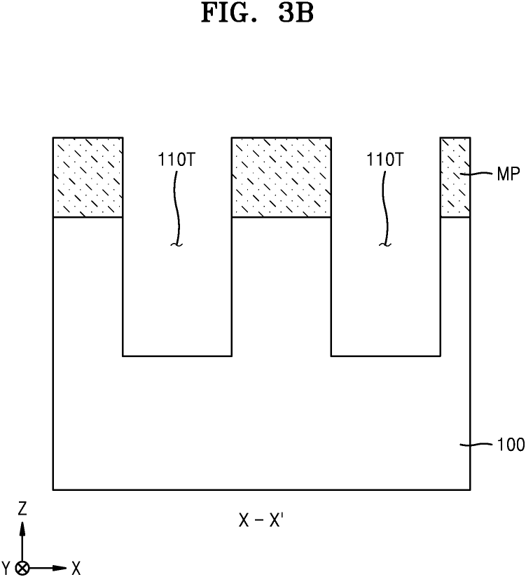

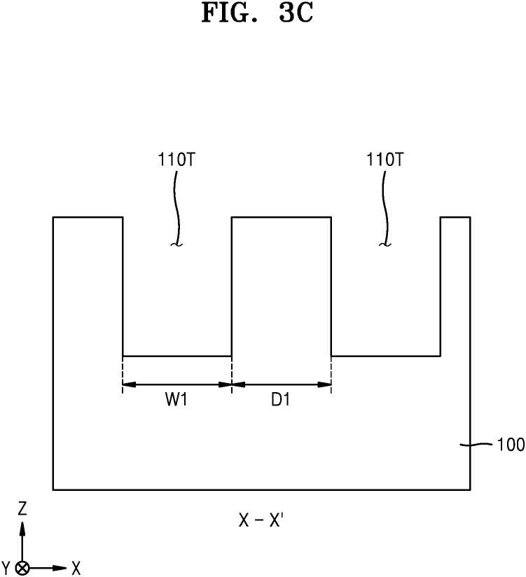

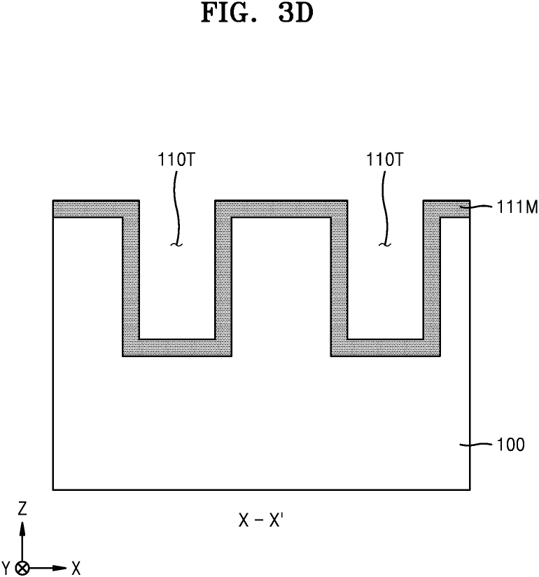

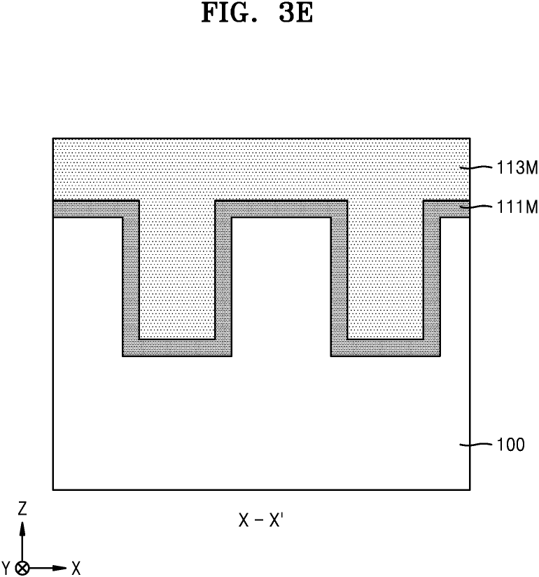

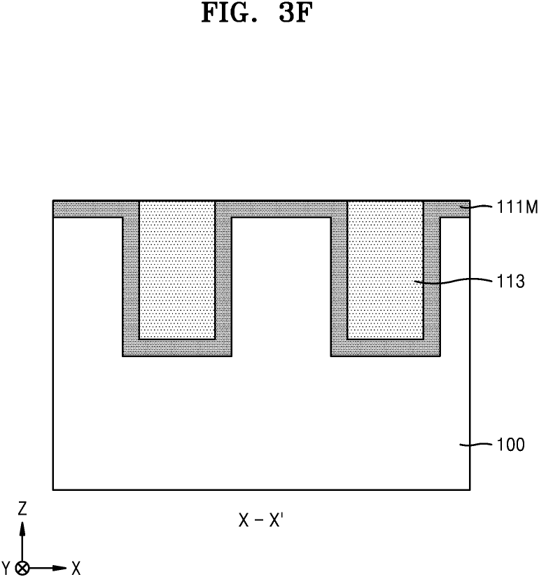

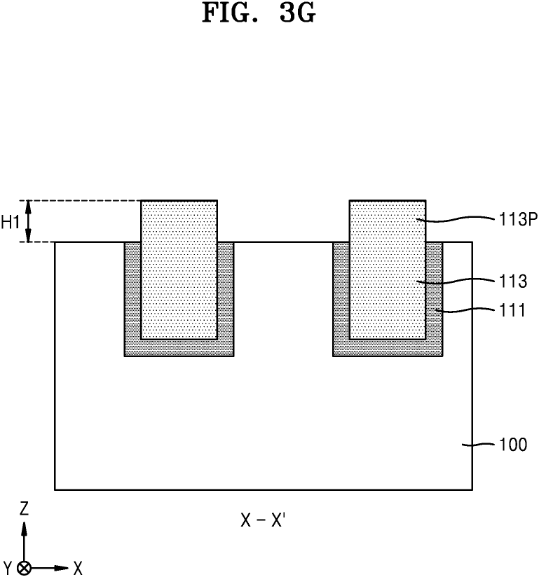

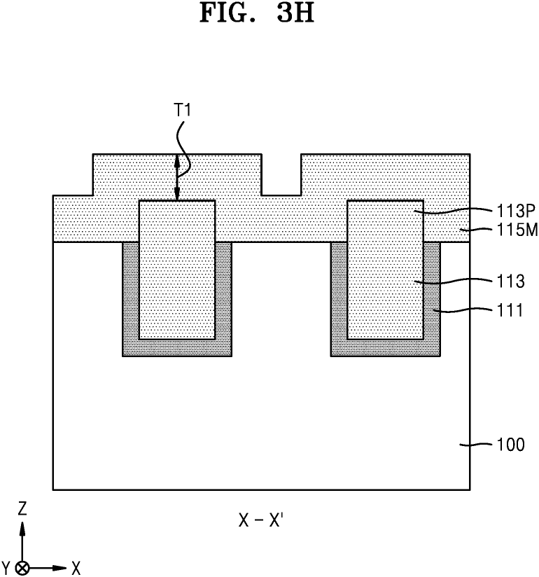

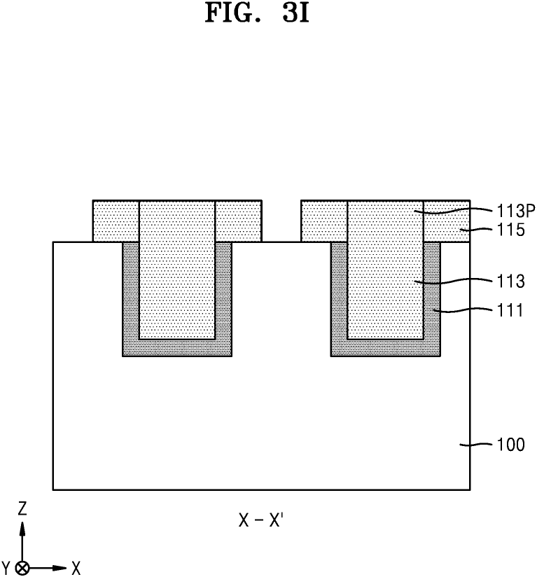

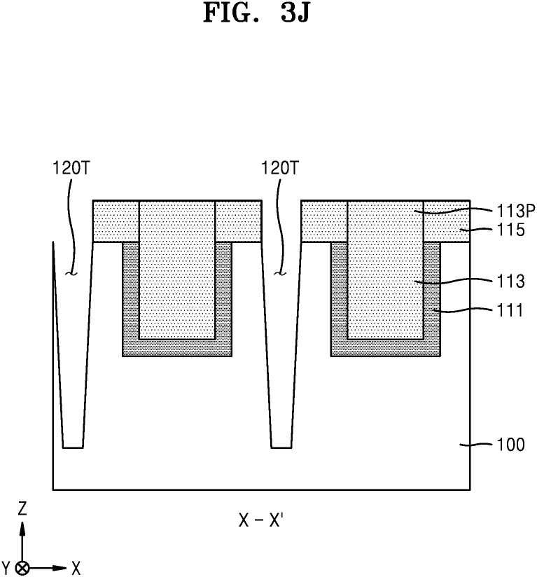

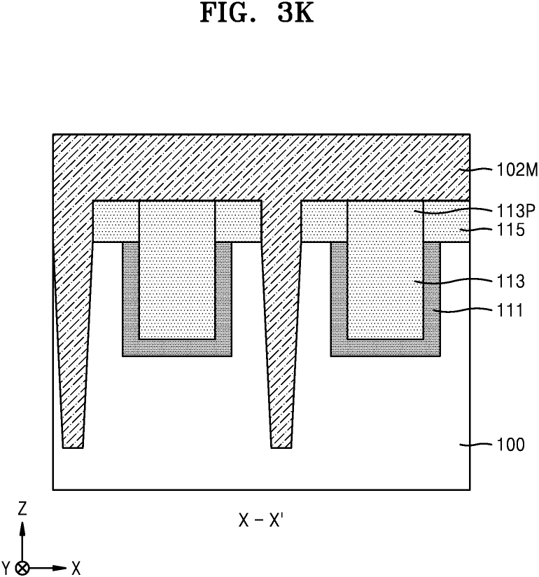

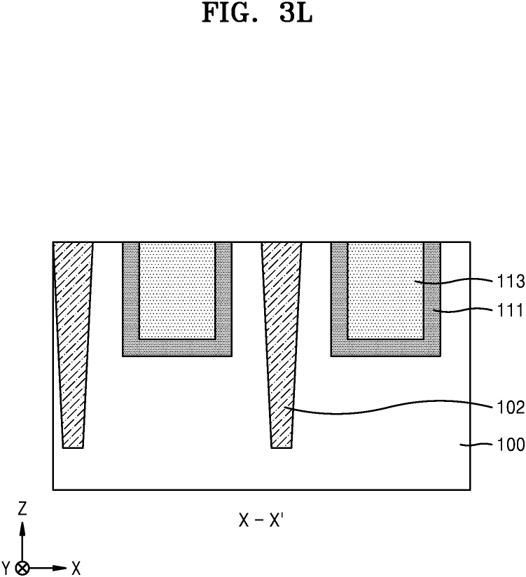

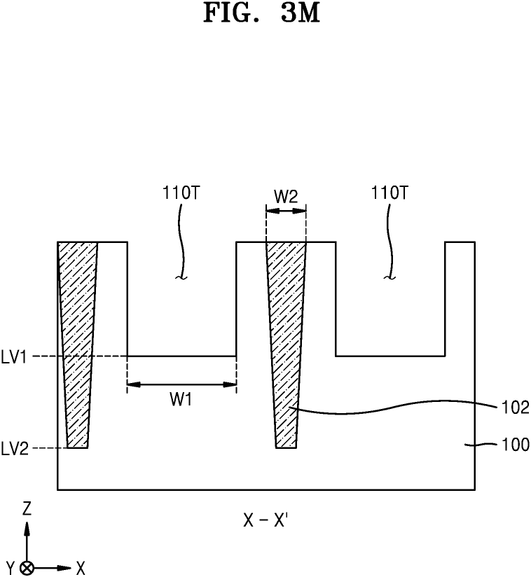

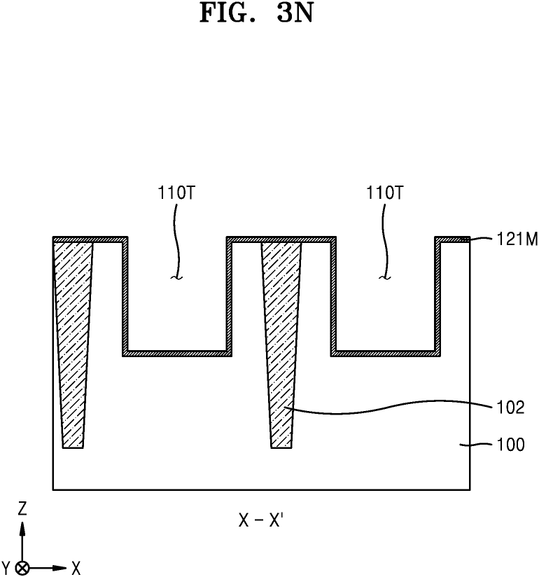

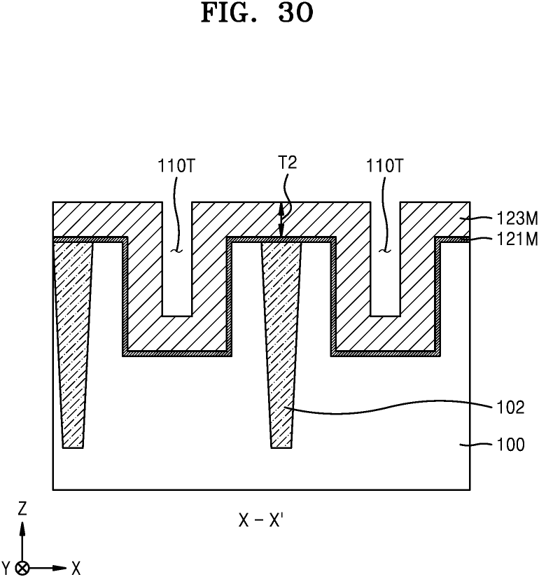

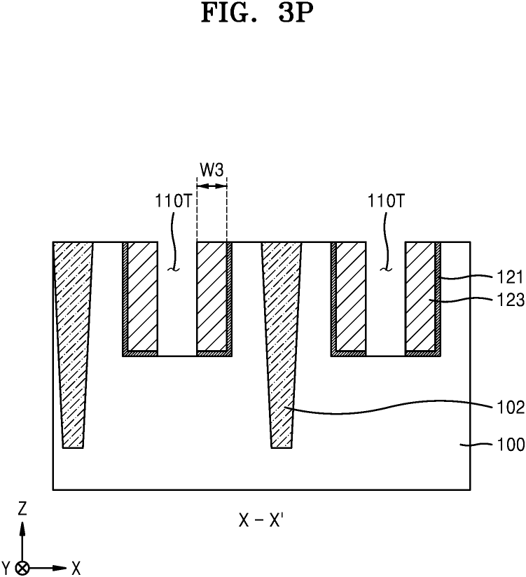

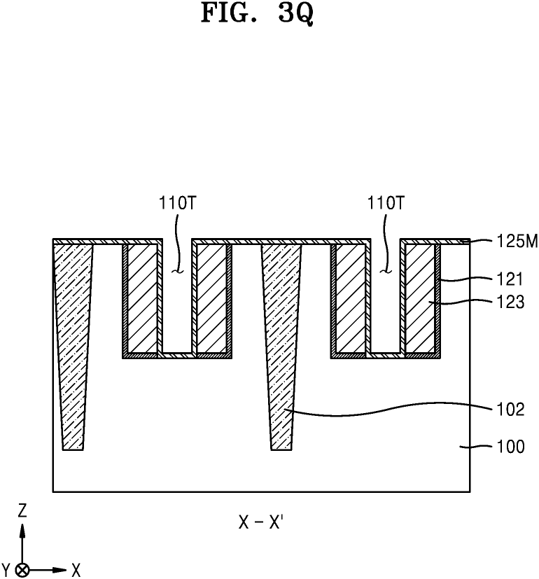

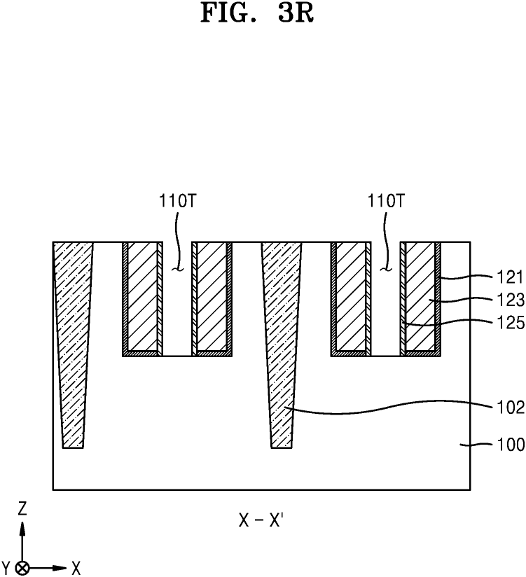

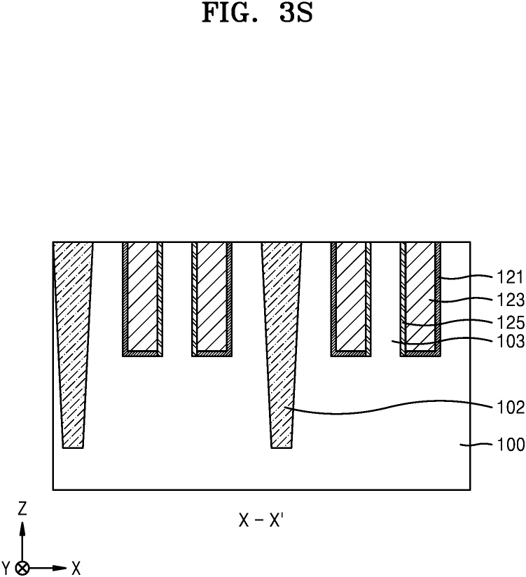

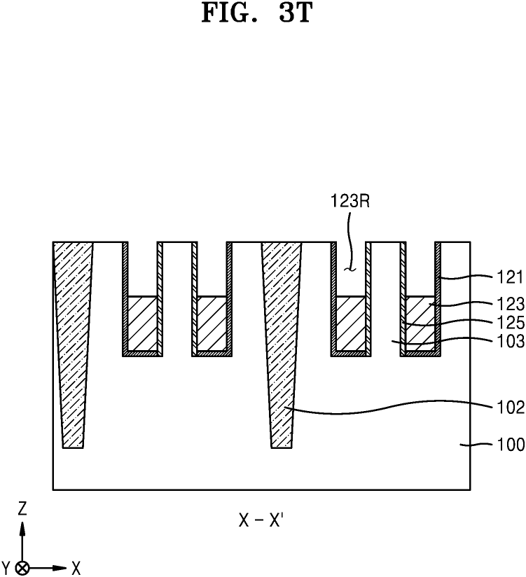

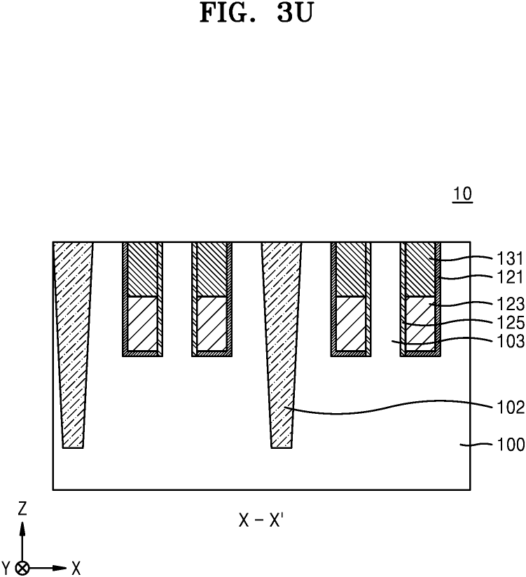

The technical features of each of first to ninth operations S110 to S190 will be described later in detail with reference to FIGS. 3A to 3U.

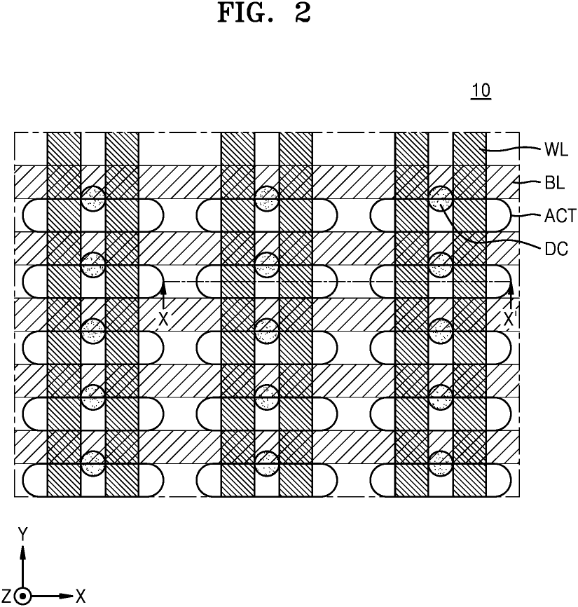

FIG. 2 is a layout diagram showing main components of a cell region of a semiconductor device according to an embodiment.

Referring to an embodiment of FIG. 2, a semiconductor device 10 may include a plurality of active regions ACT arranged to have long axes in a first horizontal direction (X direction).

A plurality of word lines WL may cross the active regions ACT and extend in parallel to one another in a second horizontal direction (Y direction) orthogonal to the first horizontal direction (X direction). A plurality of bit lines BL may extend in parallel to one another in the second horizontal direction Y above (or below) the word lines WL.

In the semiconductor device 10 according to an embodiment of the present inventive concept, the long axes of the active regions ACT may be orthogonal to the word lines WL. For example, the long axes of the active regions ACT may be parallel to the bit lines BL.

The bit lines BL may be connected to the active regions ACT via direct contacts DC. According to some embodiments, a plurality of buried contacts may be formed between two bit lines BL adjacent to each other from among the bit lines BL. Each of the buried contacts may extend to an upper portion of any one of the two bit lines BL adjacent to each other. According to some embodiments, the buried contacts may be linearly arranged in the first horizontal direction (X direction) and the second horizontal direction (Y direction).

A method of manufacturing the main components of the cell region of the semiconductor device 10 will be described in detail below.

FIGS. 3A to 3U are cross-sectional views of a method of manufacturing a semiconductor device according to embodiments, according to a process sequence.

In detail, FIGS. 3A to 3U are cross-sectional views corresponding to a cutting line X-X′ of FIG. 2 described above.

Referring to FIG. 3A, a photolithography process for forming a mask layer MP having a plurality of openings on a substrate 100 is performed.

In an embodiment, the substrate 100 may include a wafer including silicon (Si). Alternatively, the substrate 100 may include a wafer including a semiconductor element like germanium (Ge) or a compound semiconductor like silicon carbide (SiC), gallium arsenide (GaAs), indium arsenide (InAs), and indium phosphide (InP). In an embodiment, the substrate 100 may have a silicon-on-insulator (SOI) structure. Also, the substrate 100 may include a conductive region, e.g., a well doped with an impurity or a structure doped with an impurity.

The mask layer MP having a plurality of openings may be formed on the top surface of the substrate 100. According to some embodiments, the mask layer MP having a plurality of openings may be formed through an ArF lithography process or an EUV lithography process. However, embodiments of the present inventive concept are not necessarily limited thereto.

Referring to FIG. 3B, an etching process for forming a plurality of first trenches 110T in the substrate 100 is performed.

The first trenches 110T may be formed by etching the substrate 100 by using the mask layer MP having a plurality of openings as an etching mask. In an embodiment, the etching may be anisotropic etching, such as plasma etching.

Referring to FIG. 3C, a process of removing the mask layer MP (refer to FIG. 3B) having a plurality of openings from the substrate 100 is performed.

For example, in an embodiment the mask layer MP having a plurality of openings (refer to FIG. 3B) may be completely removed through an ashing process and a stripping process. However, embodiments of the present inventive concept are not necessarily limited thereto.

Therefore, the first trenches 110T may each have a first width W1 in the first horizontal direction (X direction) and may extend in the second horizontal direction (Y direction). Also, neighboring first trenches 110T may be spaced apart from each other by a first separation distance D1.

Referring to FIG. 3D, a sacrificial material layer 111M is conformally formed along inner walls of the first trenches 110T.

For example, in an embodiment the sacrificial material layer 111M may be formed by, for example, a chemical vapor deposition (CVD) method or an atomic layer deposition (ALD) method. The sacrificial material layer 111M may include silicon oxide, silicon nitride, or a combination thereof. However, embodiments of the present inventive concept are not necessarily limited thereto.

Referring to FIG. 3E, a first filling material layer 113M that fills the first trenches 110T and protrudes from the substrate 100 is formed.

The first filling material layer 113M is formed to completely fill the first trenches 110T and to cover the sacrificial material layer 111M. In an embodiment, the first filling material layer 113M may be formed by, for example, a CVD method or an ALD method. The first filling material layer 113M may include titanium nitride, tantalum nitride, or a combination thereof. The first filling material layer 113M may be a sacrificial film. In an embodiment, the sacrificial material layer 111M and the first filling material layer 113M may include different materials.

Referring to FIG. 3F, the first filling material layer 113M (refer to FIG. 3E) is planarized to expose the top surface of the sacrificial material layer 111M, thereby forming a plurality of first filling layers 113.

In an embodiment, a planarization process for the first filling material layer 113M (refer to FIG. 3E) may be, for example, a chemical mechanical polishing (CMP) process. However, embodiments of the present inventive concept are not necessarily limited thereto.

Through the planarization process, the first filling layers 113 filling (e.g., completely filling) the first trenches 110T are formed. Top surfaces of the first filling layers 113 may be positioned at substantially the same level as the top surface of the sacrificial material layer 111M (e.g., in the Z direction).

Referring to FIG. 3G, an etching process for removing a portion of the upper portion of the substrate 100 and the sacrificial material layer 111M (refer to FIG. 3F) is performed.

Only materials constituting the substrate 100 and the sacrificial material layer 111M (refer to FIG. 3F) may be selectively removed through the etching process. For example, portions of the first filling layers 113 may not be removed through the etching process. Through the etching process, the sacrificial material layer 111M (refer to FIG. 3F) is formed as a plurality of sacrificial layers 111 positioned only on the inner walls and the bottom surface of the first trenches 110T.

The first filling layers 113 each include a protrusion 113P having a certain height H1 which protrudes from the substrate 100. The height H1 of the protrusion 113P may determine the height of a spacer 115 (refer to FIG. 3I) in a process of forming the spacer 115 (refer to FIG. 3I) to be described later.

Referring to FIG. 3H, a spacer material layer 115M is formed to conformally cover an exposed surface of the substrate 100, exposed surfaces of the sacrificial layers 111, and the protrusions 113P of the first filling layers 113.

In an embodiment, the spacer material layer 115M may include a material having a high etch selectivity with respect to a material constituting the substrate 100. The etch selectivity may be quantitatively expressed through a ratio of the etch rate of one material with respect to the etch rate of another material.

In an embodiment, the spacer material layer 115M may include titanium nitride, tantalum nitride, or a combination thereof. For example, the spacer material layer 115M and the first filling layers 113 may include the same material. However, embodiments of the present inventive concept are not necessarily limited thereto. For example, in an embodiment, the spacer material layer 115M may include silicon nitride.

In an embodiment, an ALD method may be used, such that the spacer material layer 115M is formed to a uniform thickness T1. The thickness T1 of the spacer material layer 115M may determine the width of a second trench 120T in a process of forming second trenches 120T to be described later.

Referring to FIG. 3I, spacers 115 are formed by partially removing the spacer material layer 115M (refer to FIG. 3H).

For example, in an embodiment portions of the spacer material layer 115M (refer to FIG. 3H) are removed by performing an etch-back process to partially expose the top surface of the substrate 100 around the first filling layers 113. For example, the exposed top surface of the substrate 100 may be positioned between adjacent first filling layers 113. Therefore, the spacers 115 are formed on both sidewalls of the protrusions 113P in each of the first filling layers 113.

In an embodiment, the spacers 115 may be used as an etch mask for forming the second trenches 120T to be described later. The size of an exposed surface of the substrate 100 exposed by a spacer 115 may correspond to the size of the second trench 120T to be described later.

Referring to FIG. 3J, exposed portions of the substrate 100 are etched by using the spacers 115 as an etch mask, thereby forming a plurality of second trenches 120T. For example, sidewalls of adjacent spacers 115 which face each other and are opposite to the sidewalls contacting the protrusions 113P may be used as the etch mask.

In an embodiment, during the etching process, heights of the spacers 115 and the protrusions 113P may be lowered by being partially etched. Therefore, the height of the protrusion 113P and the height of the spacer 115 determined during the preceding process may be determined to be sufficient to remain in consideration of thicknesses removed during the etching process. For example, the greater the aspect ratio of the second trenches 120T is, the greater the height of the protrusion 113P and the height of the spacer 115 may be.

According to an embodiment of the present inventive concept, since the second trenches 120T are formed by using the spacers 115 formed on the sidewalls of the first filling layers 113, the second trenches 120T may be formed a constant distance apart from the first filling layers 113.

Also, according to an embodiment of the present inventive concept, since the process of forming the second trenches 120T uses self-alignment instead of a photolithography process, the second trenches 120T, which are deep trench patterns having a fine size, may be formed at uniform distribution without misalignment.

Referring to FIG. 3K, a second filling material layer 102M filling the second trenches 120T and protruding from the first filling layers 113 is formed. For example, in an embodiment the second filling material layer 102M may protrude from upper surfaces of the protrusions 113P, the spacers 115 and the second trenches 120T in the Z direction.

According to some embodiments, the second filling material layer 102M may include silicon oxide, silicon nitride, or a combination thereof. The second filling material layer 102M may be an insulating composite layer including a buffer oxide layer, a trench liner nitride layer, and a filling oxide layer. However, embodiments of the present inventive concept are not necessarily limited thereto.

In other embodiments, the second filling material layer 102M may include at least one material selected from among a high temperature oxide (HTO), a high density plasma (HDP) oxide, a tetra ethyl ortho silicate (TEOS), a boro-phospho-silicate glass (BPSG), or undoped silicate glass (USG). In an embodiment, after the process of forming the second filling material layer 102M, an annealing process for densifying the film quality may be additionally performed.

Referring to FIG. 3L, a plurality of second filling layers 102 are formed by planarizing the second filling material layer 102M (refer to FIG. 3K) to expose the top surface of the substrate 100. For example, the plurality of second filling layers 102 may be a device isolation film comprising one or more of the above-referenced insulating materials.

A planarization process may be performed on the second filling material layer 102M (refer to FIG. 3K). In an embodiment, the planarization process may be, for example, a CMP process.

Through the planarization process, the second filling layers 102 filling the second trenches 120T are formed. Also, all of the protrusions 113P and the spacers 115 are removed from the first filling layers 113 through the planarization process. Therefore, the top surfaces of the second filling layers 102 may be positioned at substantially the same level as the top surface of the substrate 100.

In an embodiment of the present inventive concept, the second filling layers 102 may serve as device isolation layers. For example, the second filling layers 102 may constitute a shallow trench isolation (STI).

Referring to FIG. 3M, all of the sacrificial layers 111 and the first filling layers 113 are removed from the first trenches 110T.

Through the removal process, the first trenches 110T surrounded by the second filling layers 102 may be re-defined in the substrate 100.

In the first horizontal direction (e.g., the X direction), the first width W1 of each of the first trenches 110T may be greater than a second width W2 of each of the second filling layers 102, and a first vertical level LV1 of the bottom surface of each of the first trenches 110T may be positioned higher from a bottom surface of the substrate 100 than a second vertical level LV2 of the bottom surface of each of the second filling layers 102.

Here, the second width W2 of each of the second filling layers 102 and the second vertical level LV2 of the bottom surface of each of the second filling layers 102 may correspond to the width of each of the second trenches 120T (refer to FIG. 3K) and the vertical level of the bottom surface of each of the second trenches 120T (refer to FIG. 3K).

Referring to FIG. 3N, a first insulating material layer 121M conformally extending along the top surface of the substrate 100 and the inner walls of the first trenches 110T is formed.

In an embodiment, the first insulating material layer 121M may be formed by, for example, a CVD method or an ALD method. The first insulating material layer 121M may include silicon oxide, silicon nitride, or a combination thereof. However, embodiments of the present inventive concept are not necessarily limited thereto.

Referring to FIG. 3O, a gate material layer 123M conformally extending on the first insulating material layer 121M along the first trenches 110T is formed.

In an embodiment, the gate material layer 123M may be formed by, for example, a physical vapor deposition (PVD) method, a CVD method, or an ALD method. The gate material layer 123M may include a metal, a metal nitride, or doped polysilicon. However, embodiments of the present inventive concept are not necessarily limited thereto.

The gate material layer 123M may be formed to have a certain thickness T2. The thickness T2 of the gate material layer 123M may determine a width W3 of a gate structure 123 (refer to FIG. 3P) in the first horizontal direction (X direction) in a process of forming a pair of gate structures 123 (refer to FIG. 3P) to be described later. For example, in an embodiment the width W3 of the gate structure 123 may be substantially equal to the thickness T2 of the gate material layer 123M.

Referring to FIG. 3P, a plurality of first insulation layers 121 and a plurality of gate structures 123 are formed by removing portions of the first insulating material layer 121M (refer to FIG. 3O) and the gate material layer 123M (refer to FIG. 3O).

In the first trenches 110T, the first insulating material layer 121M (refer to FIG. 3O) and the gate material layer 123M (refer to FIG. 3O) may be separated through an anisotropic etching process, thereby forming a pair of gate structures 123 in each of the first trenches 110T.

For example, the gate material layer 123M (refer to FIG. 3O) may be divided into two gate structures 123 respectively arranged on a first sidewall and a second sidewall of each of the first trenches 110T facing each other (e.g., in the X direction). Each of the gate structures 123 may have the width W3 in the first horizontal direction (X direction) and may extend in the second horizontal direction (Y direction).

A first insulation layer 121 may be disposed between the inner walls of each of the first trenches 110T and a gate structure 123. In other words, the gate structure 123 and the substrate 100 may not directly contact each other.

Referring to FIG. 3Q, a second insulating material layer 125M conformally extending along the top surfaces and one side surfaces of the gate structures 123 and the bottom surfaces of the first trenches 110T is formed.

In an embodiment, the second insulating material layer 125M may be formed by, for example, a CVD method or an ALD method. The second insulating material layer 125M may include silicon oxide, silicon nitride, or a combination thereof. For example, the first insulating material layer 121M and the second insulating material layer 125M may include substantially the same material.

Referring to FIG. 3R, a plurality of second insulation layers 125 are formed by removing portions of the second insulating material layer 125M (refer to FIG. 3Q) to expose the top surface of the substrate 100 and the bottom surfaces of the first trenches 110T.

The second insulating material layer 125M (refer to FIG. 3Q) may be separated in each of the first trenches 110T, thereby forming the second insulation layer 125 on one sidewall of the gate structure 123 on which the first insulation layer 121 is not formed.

Referring to FIG. 3S, a third filling layer 103 is formed between the pair of gate structures 123 in each of the first trenches 110T (refer to FIG. 3R).

In an embodiment, the third filling layer 103 may be formed through an epitaxial growth process. The third filling layer 103 may be an epitaxial growth layer grown by using the bottom surfaces of the first trenches 110T (refer to FIG. 3R) therebelow as seeds. For example, the third filling layer 103 may be formed to include the same material as the substrate 100. In an embodiment, the third filling layer 103 may include Si or silicon germanium (SiGe).

Referring to FIG. 3T, recesses 123R are formed by partially etching the gate structures 123.

The recesses 123R recessed into the first trenches 110T (refer to FIG. 3R) may be formed on the gate structures 123. Therefore, the top surface of each of the gate structures 123 may be positioned at a level lower than that of the top surface of the substrate 100.

Referring to FIG. 3U, a plurality of capping layers 131 are formed on the gate structures 123 to fill the recesses 123R (refer to FIG. 3T).

The capping layers 131 formed on the gate structures 123 may include an insulating material. In an embodiment, the capping layers 131 may include, for example, silicon oxide, silicon nitride, or a combination thereof. However, embodiments of the present inventive concept are not necessarily limited thereto.

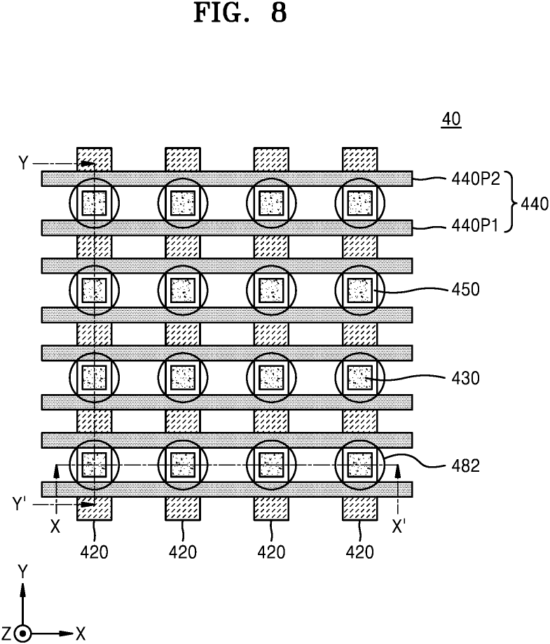

According to some embodiments, each of the gate structures 123 may be a buried gate structure including a conductive material. For example, each of the gate structures 123 may correspond to a word line WL (refer to FIG. 2). However, embodiments of the present inventive concept are not necessarily limited thereto. For example, in other embodiments, each of the gate structures 123 may be a vertical gate structure including a conductive material and each of the gate structures 123 may correspond to a gate electrode 440 (refer to FIG. 8).

Through the processes, the semiconductor device 10 according to an embodiment of the present inventive concept may be manufactured.

According to the method of manufacturing the semiconductor device 10 of an embodiment of the present inventive concept, since trenches formed in a subsequent process are self-aligned with previously formed trenches, misalignment may be prevented, and, since trenches have uniform distribution, the reliability of the semiconductor device 10 may be increased.

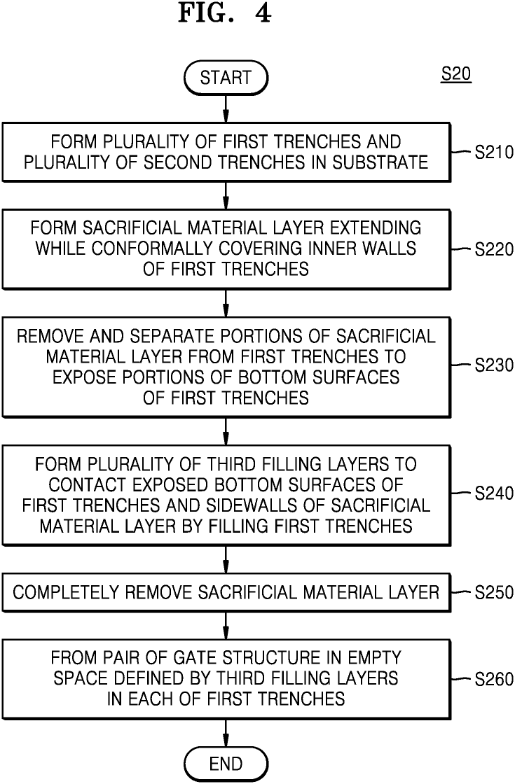

FIG. 4 is a block diagram showing a method of manufacturing a semiconductor device according to an embodiment.

Referring to FIG. 4, a method S20 of manufacturing a semiconductor device may include first to sixth operations S210 to S260.

In some embodiments, particular operations may be performed in an order different from that described below. For example, two successively described operations may be performed substantially simultaneously or may be performed in an order opposite to the order described below.

The method S20 of manufacturing a semiconductor device according to an embodiment of the present inventive concept may include a first operation S210 for forming a plurality of first trenches and a plurality of second trenches in a substrate, a second operation S220 for forming a sacrificial material layer extending while conformally covering inner walls of the first trenches, a third operation S230 for removing and separating a portion of the sacrificial material layer from the first trenches, a fourth operation S240 for forming a plurality of third filling layer to contact exposed bottom surfaces of the first trenches and sidewalls of the sacrificial material layer by filling the first trenches, a fifth operation S250 for completely removing the sacrificial material layer, and a sixth operation S260 for forming a pair of gate structures in an empty space defined by the third filling layer in each of the first trenches.

The first operation S210 may include operations substantially identical to first to sixth operations S110 to S160 (refer to FIG. 1) of the above-described method S10 (refer to FIG. 1) of manufacturing a semiconductor device. Therefore, detailed descriptions thereof will be omitted for economy of description.

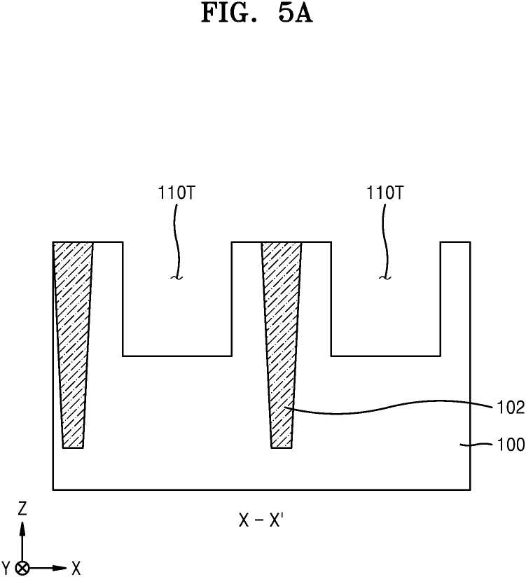

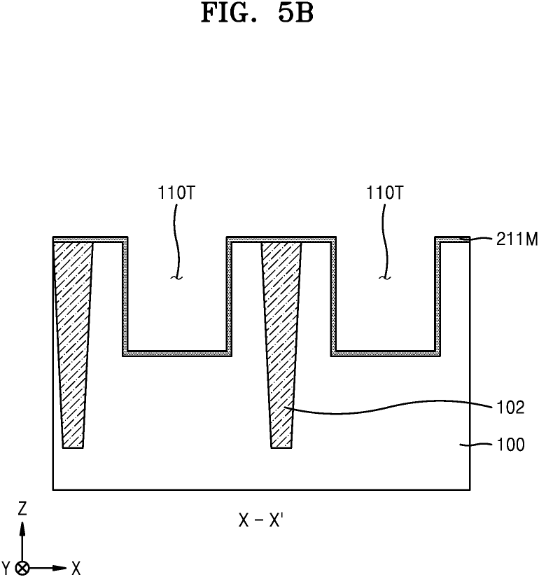

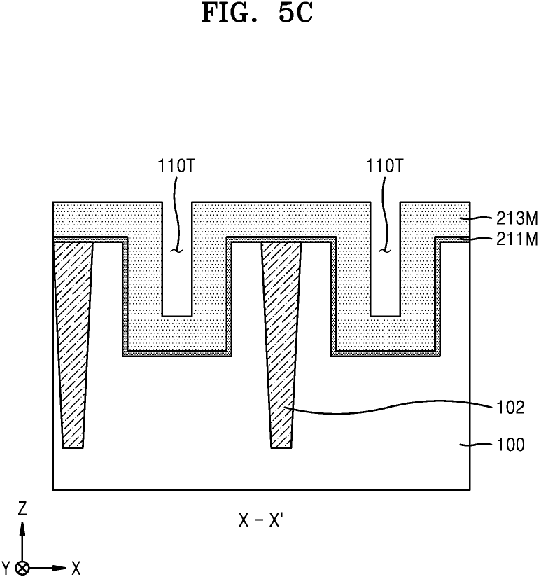

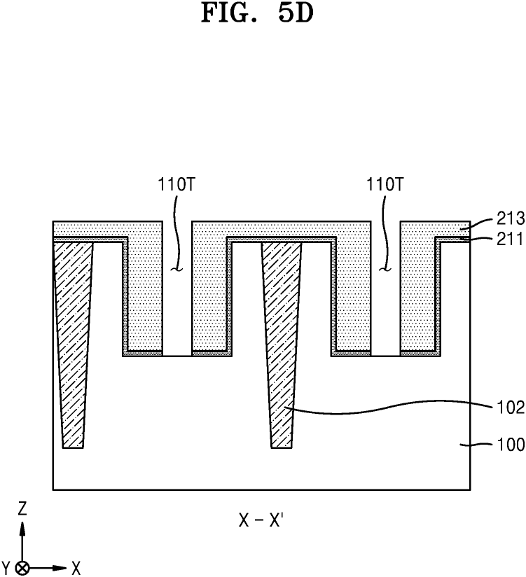

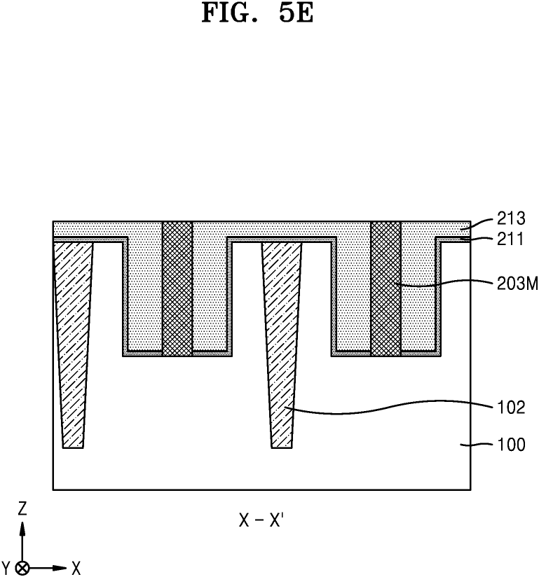

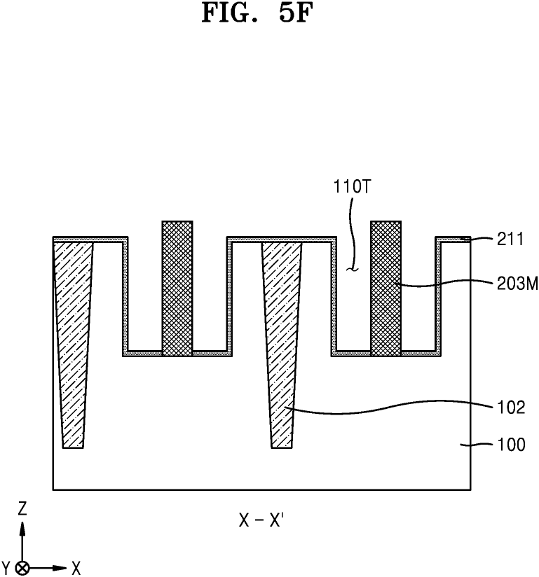

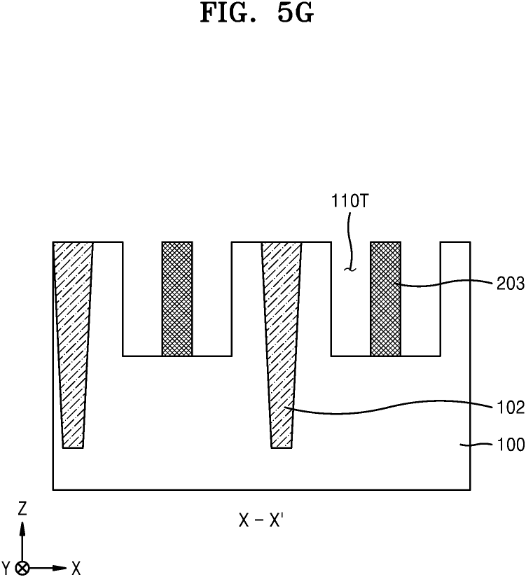

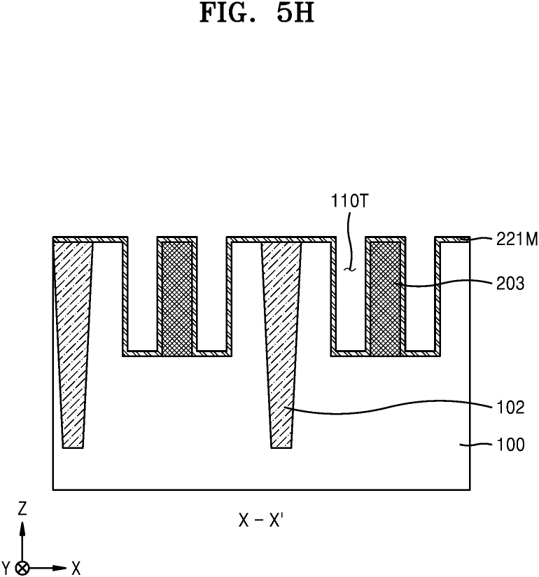

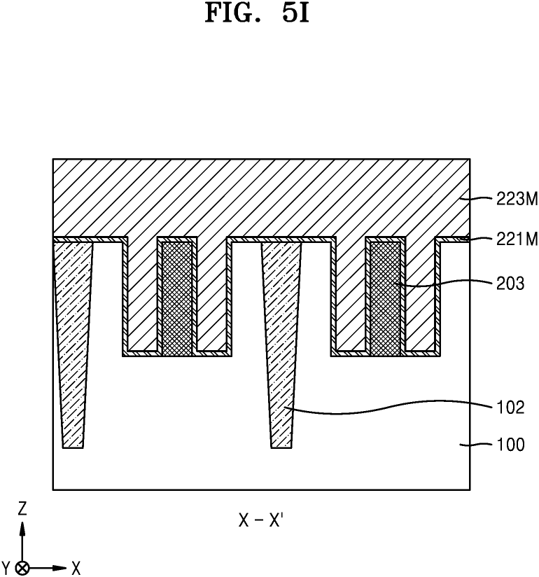

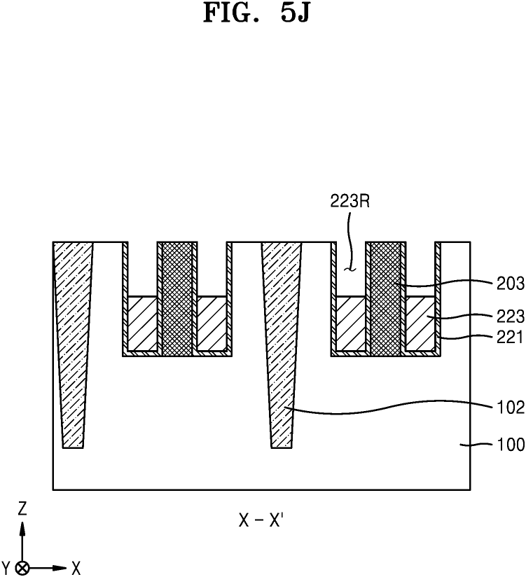

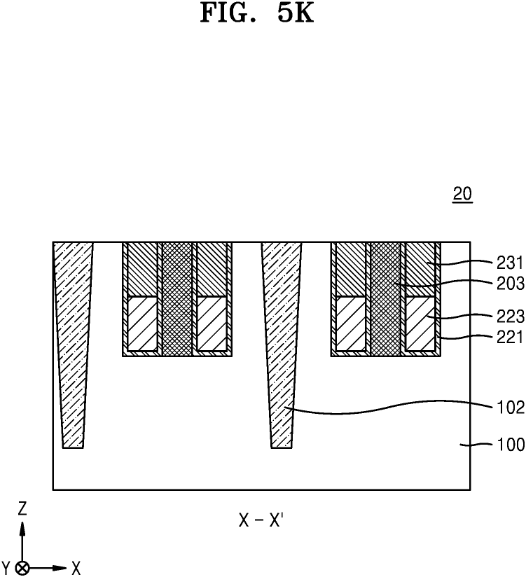

The technical features of each of first to sixth operations S210 to S260 will be described later in detail with reference to FIGS. 5A to 5K.

FIGS. 5A to 5K are cross-sectional views of a method of manufacturing a semiconductor device according to embodiments, according to a process sequence.

FIGS. 5A to 5K are cross-sectional views corresponding to a cutting line X-X′ of FIG. 2 described above.

Referring to FIG. 5A, the first trenches 110T and the second filling layers 102 are formed in the substrate 100.

In the method of manufacturing a semiconductor device 20 (refer to FIG. 5K), the process of forming the first trenches 110T and the second filling layers 102 in the substrate 100 is substantially identical to that described above with reference to FIGS. 3A to 3M. Therefore, detailed descriptions thereof will be omitted for economy of description.

Referring to FIG. 5B, a first sacrificial material layer 211M is conformally formed along inner walls of the first trenches 110T and a top surface of the substrate 100.

In an embodiment, the first sacrificial material layer 211M may be formed by, for example, a CVD method or an ALD method. The first sacrificial material layer 211M may include silicon oxide, silicon nitride, or a combination thereof. However, embodiments of the present disclosure are not necessarily limited thereto.

Referring to FIG. 5C, a second sacrificial material layer 213M conformally extending on the first sacrificial material layer 211M along the first trenches 110T is formed.

In an embodiment, the second sacrificial material layer 213M may be formed by, for example, a CVD method or an ALD method. The second sacrificial material layer 213M may include titanium nitride, tantalum nitride, or a combination thereof. For example, the first sacrificial material layer 211M and the second sacrificial material layer 213M may include different materials.

Referring to FIG. 5D, a plurality of first sacrificial layers 211 and a plurality of second sacrificial layers 213 are formed by removing portions of the first sacrificial material layer 211M (refer to FIG. 5C) and the second sacrificial material layer 213M (refer to FIG. 5C) to expose bottom surfaces of the first trenches 110T.

In an embodiment, an empty space defined by sidewalls of the first sacrificial layers 211 and sidewalls of the second sacrificial layers 213 may be formed in each of the first trenches 110T by separating the first sacrificial material layer 211M (refer to FIG. 5C) and the second sacrificial material layer 213M (refer to FIG. 5C) through an anisotropic etching process in the first trenches 110T. However, embodiments of the present disclosure are not necessarily limited thereto.

Referring to FIG. 5E, a third filling material layer 203M is formed between a pair of second sacrificial layers 213 in each of the first trenches 110T (refer to FIG. 5D).

In an embodiment, the third filling material layer 203M may be formed by, for example, a PVD method, a CVD method, or an ALD method. The third filling material layer 203M may include a metal, a metal nitride, or doped polysilicon. However, embodiments of the present inventive concept are not necessarily limited thereto, and the third filling material layer 203M may include an insulating material like silicon oxide or silicon nitride.

Referring to FIG. 5F, all of the second sacrificial layers 213 are removed to expose the first sacrificial layers 211 and the third filling material layer 203M.

The third filling material layer 203M may be disposed to protrude from the top surface of the substrate 100. Also, the third filling material layer 203M may be disposed to protrude from the top surface of the first sacrificial layers 211.

Referring to FIG. 5G, all of the first sacrificial layers 211 are removed to expose inner walls of the first trenches 110T.

In an embodiment, during the removal process, the height of the third filling material layer 203M (refer to FIG. 5F) may also be lowered by being partially etched. Therefore, the height of the third filling material layer 203M (refer to FIG. 5F) determined during the preceding process may be determined to be sufficient to remain in consideration of thicknesses removed during the removal process.

The third filling material layer 203M (refer to FIG. 5F) is partially removed to form third filling layers 203. The top surfaces of the third filling layers 203 may be positioned at the same level as the top surface of the substrate 100. Therefore, an empty space defined by the third filling layers 203 may be formed in the first trenches 110T.

Referring to FIG. 5H, an insulating material layer 221M conformally extending along the inner walls of the first trenches 110T and outer walls of the third filling layers 203 is formed.

In an embodiment, the insulating material layer 221M may be formed by, for example, a CVD method or an ALD method. The insulating material layer 221M may include silicon oxide, silicon nitride, or a combination thereof. However, embodiments of the present disclosure are not necessarily limited thereto.

Referring to FIG. 51, a gate material layer 223M that fills the first trenches 110T and protrudes from the substrate 100 is formed.

The gate material layer 223M is formed to completely fill the first trenches 110T and to cover the insulating material layer 221M. In an embodiment, the gate material layer 223M may be formed by, for example, a PVD method, a CVD method, or an ALD method. The gate material layer 223M may include a metal, a metal nitride, or doped polysilicon. However, embodiments of the present disclosure are not necessarily limited thereto.

Referring to FIG. 5J, the gate material layer 223M is partially etched to form a plurality of gate structures 223.

Recesses 223R recessed into the first trenches 110T (refer to FIG. 5H) may be formed on the gate structures 223. Therefore, the top surface of each of the gate structures 223 may be positioned at a level lower than that of the top surface of the substrate 100.

Referring to FIG. 5K, a plurality of capping layers 231 are formed on the gate structures 223 to fill the recesses 223R (refer to FIG. 5J).

The capping layers 231 formed on the gate structures 223 may include an insulating material. In an embodiment, the capping layers 231 may include, for example, silicon oxide, silicon nitride, or a combination thereof. However, embodiments of the present disclosure are not necessarily limited thereto.

Through the processes, the semiconductor device 20 according to an embodiment of the present inventive concept may be manufactured.

According to the method of manufacturing the semiconductor device 20 of an embodiment of the present inventive concept, since trenches formed in a subsequent process are self-aligned with previously formed trenches, misalignment may be prevented, and, since trenches have uniform distribution, the reliability of the semiconductor device 20 may be increased.

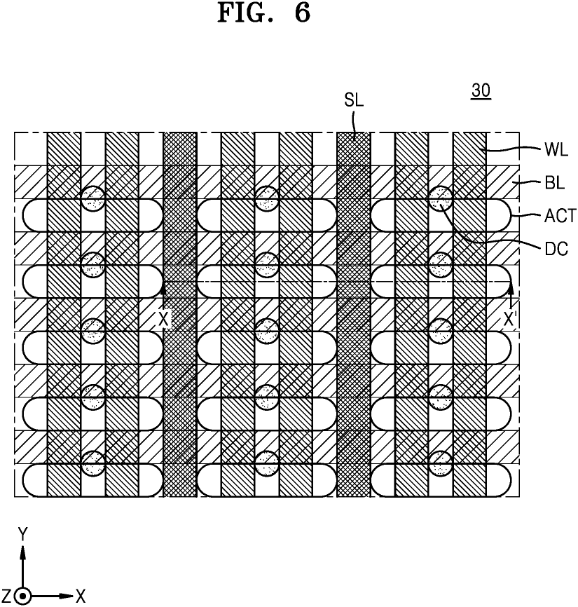

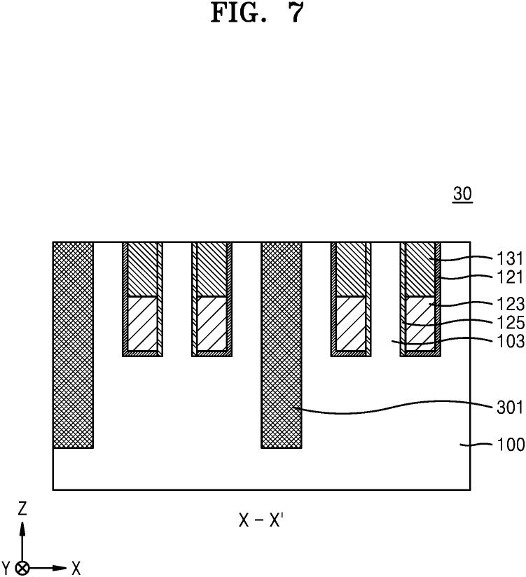

FIG. 6 is a layout diagram showing main components of a cell region of a semiconductor device according to an embodiment, and FIG. 7 is a cross-sectional view of a cross-sectional configuration taken along a line X-X′ of FIG. 6.

Most of components constituting a semiconductor device 30 described below and materials constituting the components are substantially the same as or similar to those described above with reference to FIGS. 2 and 3A to 3U. Therefore, for convenience of explanation, descriptions below will focus on differences from the semiconductor device 10 described above.

Referring to FIGS. 6 and 7 together, the semiconductor device 30 may include a plurality of shield lines SL extending in parallel to one another in the second horizontal direction (Y direction).

The semiconductor device 30 may include the active regions ACT arranged to have long axes in a first horizontal direction (X direction).

The word lines WL may cross the active regions ACT and extend in parallel to one another in the second horizontal direction (Y direction) orthogonal to the first horizontal direction (X direction). The bit lines BL may extend in parallel to one another in the second horizontal direction Y above (or below) the word lines WL.

The bit lines BL may be connected to the active regions ACT via the direct contacts DC.

In the semiconductor device 30 of an embodiment of FIG. 6, a shield line SL extending in the second horizontal direction (Y direction) may be formed between two active regions ACT adjacent to each other (e.g., in the X direction) from among the active regions ACT. For example, in the process of forming the second filling layers 102 (refer to FIG. 3L), a plurality of shield structures 301 may be formed. In an embodiment, the shield structures 301 may be buried in portions of the second filling layers 102 (refer to FIG. 3L) and may extend in parallel to one another in the second horizontal direction (Y direction).

As shown in an embodiment of FIG. 7, top surfaces of the shield structures 301 may be positioned at substantially the same level as the top surface of the substrate 100 (e.g., in the Z direction) in the semiconductor device 30. The shield structures 301 may each include a conductive material surrounded by an insulating material. For example, in each of the shield structures 301, an insulation liner may be disposed at a portion in contact with the substrate 100, and a conductive material may be disposed to fill the inside of the insulation liner.

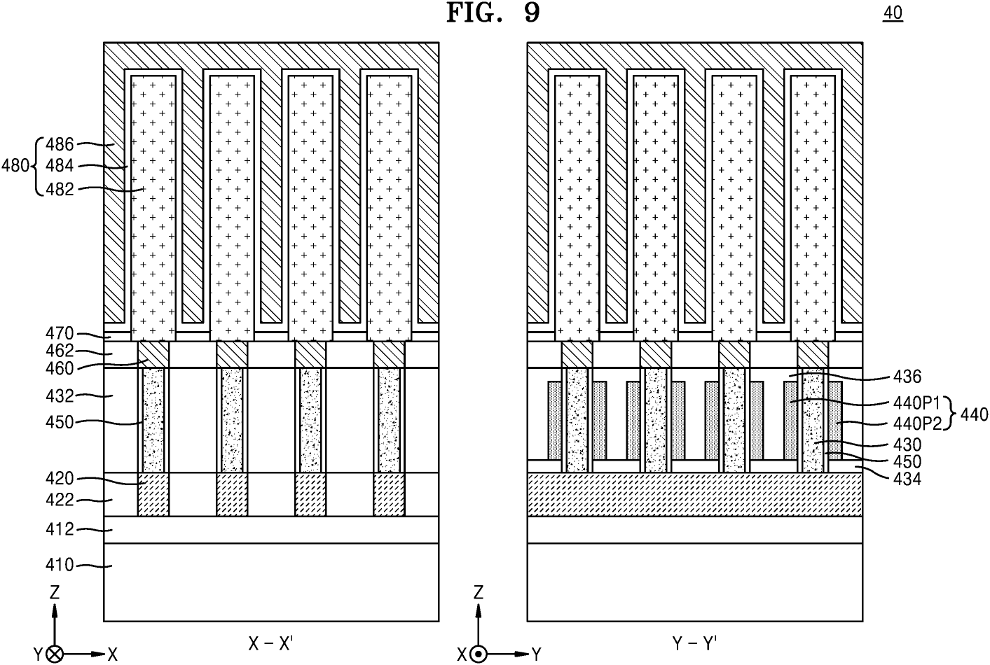

FIG. 8 is a layout diagram showing a semiconductor device according to an embodiment, and FIG. 9 is a cross-sectional view of a cross-sectional configuration along a line X-X′ and a line Y-Y′ of FIG. 8.

Referring to FIGS. 8 and 9 together, a semiconductor device 40 may include a substrate 410, a plurality of first conductive lines 420, channel layers 430, gate electrodes 440, gate insulation layers 450, and capacitor structures 480.

The semiconductor device 40 may be a memory device including a vertical channel transistor (VCT). The vertical channel transistor may refer to a structure in which the channel length of a channel layer 430 extends in a vertical direction (e.g., the Z direction) from the substrate 410.

A lower insulation layer 412 may be disposed on the substrate 410, and, on the lower insulation layer 412, the first conductive lines 420 may be spaced apart from one another in the first horizontal direction (X direction) and may extend in the second horizontal direction (Y direction). A plurality of first insulation patterns 422 may be arranged on the lower insulation layer 412 to fill spaces between the first conductive lines 420. The first insulation patterns 422 may extend in the second horizontal direction (Y direction), and top surfaces of the first insulation patterns 422 may be positioned at the same level as top surfaces of the first conductive lines 420. The first conductive lines 420 may serve as bit lines of the semiconductor device 40.

According to some embodiments, the first conductive lines 420 may include a doped polysilicon, a metal, a conductive metal nitride, a conductive metal silicide, a conductive metal oxide, or a combination thereof. For example, in an embodiment the first conductive lines 420 may include a doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOₓ, or a combination thereof. However, embodiments of the present inventive concept are not necessarily limited thereto. The first conductive lines 420 may include a single layer or multiple layers of the above-stated materials. According to some embodiments, the first conductive lines 420 may include a 2-dimensional semiconductor material, wherein the 2-dimensional semiconductor material may include, for example, graphene, carbon nanotube, or a combination thereof.

The channel layers 430 may be arranged in a matrix-like shape spaced apart from one another in the first horizontal direction (X direction) and the second horizontal direction (Y direction) above the first conductive lines 420. The channel layer 430 may have a first width in the first horizontal direction (X direction) and a first height in the vertical direction (Z direction). The first height may be greater than the first width. In an embodiment, a bottom portion of the channel layer 430 may serve as a first source/drain region, an upper portion of the channel layer 430 may serve as a second source/drain region, and a portion of the channel layer 430 between first and second source/drain regions may serve as a channel region.

According to some embodiments, the channel layer 430 may include an oxide semiconductor, e.g., the oxide semiconductor may include InₓGa_{y}Zn_{z}O, InₓGa_{y}Si_{z}O, InₓSn_{y}Zn_{z}O, lnₓZn_{y}O, ZnₓO, ZnₓSn_{y}O, ZnₓO_{y}N, Zr-Zn_{y}Sn_{z}O, SnₓO, HfₓIn_{y}Zn_{z}O, HfₓIn_{y}ZnO AlₓZn_{y}Sn_{z}O, YbₓGa_{y}Zn_{z}O, InₓGa_{y}O, or a combination thereof. However, embodiments of the present inventive concept are not necessarily limited thereto. The channel layer 430 may include a single layer or multiple layers of the oxide semiconductor. According to some embodiments, the channel layer 430 may have a bandgap energy greater than that of silicon. For example, the channel layer 430 may have a bandgap energy in a range from about 1.5 eV to about 5.6 eV. For example, the channel layer 430 may exhibit optimal channel performance when the channel layer 430 has a bandgap energy in a range from about 2.0 eV to about 4.0 eV. For example, the channel layer 430 may be polycrystalline or amorphous. However, embodiments of the present inventive concept are not necessarily limited thereto. According to some embodiments, the channel layer 430 may include a 2-dimensional semiconductor material, wherein the 2-dimensional semiconductor material may include, for example, graphene, carbon nanotubes, or a combination thereof.

The gate electrodes 440 may extend in the first horizontal direction (X direction) on both sidewalls of the channel layer 430. The gate electrodes 440 may each include a first sub-gate electrode 440P1 facing a first sidewall of the channel layer 430 and a second sub-gate electrode 440P2 facing a second sidewall of the channel layer 430 opposite to the first sidewall of the channel layer 430. As one channel layer 430 is disposed between the first sub-gate electrode 440P1 and the second sub-gate electrode 440P2, the semiconductor device 40 may have a dual-gate transistor structure. However, embodiments of the present inventive concept are not necessarily limited thereto, and a single-gate transistor structure may be implemented as the second sub-gate electrode 440P2 is omitted and only the first sub-gate electrode 440P1 facing the first sidewall of the channel layer 430 is formed.

In the semiconductor device 40 of the present embodiment, the gate electrode 440 may be formed by using the above-described method S10 or S20 of manufacturing a semiconductor device. For example, the gate electrode 440 may be formed at uniform distribution through a process of forming trenches and a process of filling the same.

The gate electrodes 440 may include a metal, a metal nitride, a metal carbide, or a combination thereof. According to some embodiments, the gate electrodes 440 may include Ti, TiN, Ta, TaN, W, WN, TiSiN, WSiN, or a combination thereof. However, embodiments of the present inventive concept are not necessarily limited thereto.

The gate insulation layer 450 may surround sidewalls of the channel layer 430, and may be provided between the channel layer 430 and the gate electrode 440. For example, all of sidewalls of the channel layer 430 may be surrounded by the gate insulation layer 450, and portions of sidewalls of the gate electrode 440 may contact the gate insulation layer 450. According to other embodiments, the gate insulation layer 450 may extend in the direction in which the gate electrode 440 extends (e.g., the first horizontal direction), and only two sidewalls of the channel layer 430 facing the gate electrodes 440 from among the sidewalls of the channel layer 430 may contact the gate insulation layer 450.

According to some embodiments, the gate insulation layer 450 may include silicon oxide, silicon oxynitride, a high-k material having a higher dielectric constant than silicon oxide, or a combination thereof. The high-k material may include a metal oxide or a metal oxynitride. For example, the high-k material that may constitute the gate insulation layer 450 may include, but is not necessarily limited to, HfO₂, HfSiO, HfSiON, HfTaO, HfTiO, HfZrO, ZrO₂, Al₂O₃, or a combination thereof.

A plurality of second insulation patterns 432 may extend in the second horizontal direction (Y direction) on the first insulation patterns 422, and the channel layer 430 may be disposed between two second insulation patterns 432 adjacent to each other from among the second insulation patterns 432. Also, a first filling layer 434 and a second filling layer 436 may be arranged in a space between two channel layers 430 adjacent to each other between two second insulation patterns 432 adjacent to each other. The first filling layer 434 may be disposed at the bottom of the space between two channel layers 430 adjacent to each other and may contact the first conductive lines 420, and the second filling layer 436 may be formed on the first filling layer 434 to fill the remaining of the space between the two channel layers 430 adjacent to each other. The top surface of the second filling layer 436 may be positioned at the same level as the top surface of the channel layer 430, and the second filling layer 436 may cover the top surface of the gate electrode 440. Alternatively, the second insulation patterns 432 may be formed as a material layer continuous with the first insulation patterns 422, or the second filling layer 436 may be formed as a continuous material layer with the first filling layer 434.

Capacitor contacts 460 may be arranged on the channel layers 430. The capacitor contacts 460 may be arranged to vertically overlap the channel layers 430 and may be arranged in a matrix-like shape spaced apart from one another in the first horizontal direction (X direction) and the second horizontal direction (Y direction). In an embodiment, the capacitor contacts 460 may include a doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOₓ, or a combination thereof. However, embodiments of the present inventive concept are not necessarily limited thereto. An upper insulation layer 462 may surround sidewalls of the capacitor contacts 460 on the second insulation patterns 432 and the second filling layer 436.

An etch stop layer 470 may be disposed on the upper insulation layer 462, and the capacitor structure 480 may be disposed on the etch stop layer 470. The capacitor structure 480 may include a lower electrode 482, a capacitor dielectric layer 484, and an upper electrode 486.

The lower electrode 482 may penetrate through the etch stop layer 470 and may be electrically connected to the top surface of the capacitor contact 460. In an embodiment, the lower electrode 482 may be formed in a pillar-like shape extending in the vertical direction (Z direction). However, embodiments of the present inventive concept are not necessarily limited thereto. According to some embodiments, lower electrodes 482 may be arranged to vertically overlap the capacitor contacts 460 and may be arranged in a matrix-like shape spaced apart from one another in the first horizontal direction (X direction) and the second horizontal direction (Y direction). Alternatively, landing pads may be further disposed between the capacitor contacts 460 and the lower electrodes 482, and thus the lower electrodes 482 may be arranged in a hexagonal shape.

While embodiments of the present inventive concept has been particularly shown and described with reference to non-limiting embodiments thereof, it will be understood that various changes in form and details may be made therein without departing from the spirit and scope of the present inventive concept.

What is claimed is:

1. A method of manufacturing a semiconductor device, the method comprising:
forming a plurality of first trenches in a substrate, the plurality of first trenches is spaced apart from each other in a first horizontal direction and each of the plurality of first trenches extends in a second horizontal direction orthogonal to the first horizontal direction;
forming a plurality of first filling layers that fills the plurality of first trenches, each of the plurality of first filling layers has protrusions extending to protrude from the substrate;
forming spacers on sidewalls of the protrusions of the plurality of first filling layers, the spacers expose portions of the substrate between adjacent first filling layers of the plurality of first filling layers;
forming a plurality of second trenches around the plurality of first trenches by etching the portions of the substrate exposed by the spacers;
forming a plurality of second filling layers filling the plurality of second trenches and having top surfaces positioned at a same level as a top surface of the substrate;
removing all of the plurality of first filling layers and the spacers;
forming a gate material layer conformally covering inner walls of the plurality of first trenches;
forming a pair of gate structures in each of the plurality of first trenches by separating the gate material layer; and
forming a third filling layer between the pair of gate structures in each of the plurality of first trenches.

2. The method of claim 1, wherein the forming of the plurality of first filling layers comprises:
filling the plurality of first trenches with a first filling layer material; and
removing an upper portion of the substrate by a first thickness to expose sidewalls of the protrusion.

3. The method of claim 1, wherein the forming of the spacers comprises:
forming a spacer material conformally covering the substrate and the protrusion; and
partially etching the spacer material to expose portions of the substrate between adjacent first filling layers of the plurality of first filling layers.

4. The method of claim 1, wherein:
each of the plurality of first filling layers is a sacrificial film;
each of the plurality of second filling layers is a device isolation film comprising an insulating material; and
the third filling layer is an epitaxial growth layer.

5. The method of claim 1, wherein:
each of the plurality of first filling layers is a sacrificial film; and
at least one of the plurality of second filling layers and the third filling layer comprises a conductive material.

6. The method of claim 5, wherein a portion of each of the plurality of second filling layers comprises a shield structure extending in the second horizontal direction and comprising a conductive material.

7. The method of claim 1, wherein:
a width of each of the plurality of first trenches in the first horizontal direction is greater than a width of each of the plurality of second trenches in the first horizontal direction; and
a vertical level of a bottom surface of each of the plurality of first trenches is positioned higher than a vertical level of a bottom surface of each of the plurality of second trenches.

8. The method of claim 1, wherein a width of each of the pair of gate structures in the first horizontal direction is substantially equal to a thickness of the gate material layer.

9. The method of claim 1, wherein:
in the substrate, a plurality of active regions surrounded by the plurality of second filling layers have long axes in the first horizontal direction; and
the direction of the long axes of the active regions is orthogonal to a direction in which the pair of gate structures extend.

10. The method of claim 1, wherein each of the pair of gate structures is a word line constituting a vertical channel transistor.

11. A method of manufacturing a semiconductor device, the method comprising:
forming a plurality of first trenches in a substrate, the plurality of first trenches is spaced apart from each other in a first horizontal direction and each of the plurality of first trenches extends in a second horizontal direction orthogonal to the first horizontal direction;
forming a plurality of first filling layers that fills the plurality of first trenches, each of the plurality of first filling layers has protrusions extending to protrude from the substrate;
forming spacers on sidewalls of the protrusions of the plurality of first filling layers, the spacers expose portions of the substrate between adjacent first filling layers of the plurality of first filling layers;
forming a plurality of second trenches around the plurality of first trenches by etching the portions of the substrate exposed by the spacers;
forming a plurality of second filling layers filling the plurality of second trenches and having top surfaces positioned at a same level as a top surface of the substrate;
removing all of the plurality of first filling layers and the spacers;
forming a sacrificial material layer conformally covering inner walls of the plurality of first trenches;
removing and separating portions of the sacrificial material layer from the plurality of first trenches to expose portions of a bottom surface of the plurality of first trenches;
forming a plurality of third filling layers filling the plurality of first trenches and directly contacting the exposed portions of the bottom surfaces of the plurality of first trenches and sidewalls of the sacrificial material layer;
completely removing the sacrificial material layer; and
forming a pair of gate structures in an empty space defined by the plurality of third filling layers in each of the plurality of first trenches.

12. The method of claim 11, wherein:
each of the plurality of first filling layers is a sacrificial film;
each of the plurality of second filling layers is a device isolation film comprising an insulating material; and
each of the plurality of third filling layers is an epitaxial growth layer.

13. The method of claim 11, wherein:
each of the plurality of first filling layers is a sacrificial film; and
at least one of the plurality of second filling layers and the plurality of third filling layers comprises a conductive material.

14. The method of claim 13, wherein a portion of each of the plurality of second filling layers comprises a shield layer extending in the second horizontal direction and comprising a conductive material.

15. The method of claim 11, wherein the plurality of first trenches and the plurality of second trenches are alternately formed in the first horizontal direction.

16. A method of manufacturing a semiconductor device, the method comprising:
forming a mask layer having a plurality of openings on a substrate;
forming a plurality of first trenches by etching the substrate using the mask layer as an etching mask, the plurality of first trenches is spaced apart from each other in a first horizontal direction and each of the plurality of first trenches extends in a second horizontal direction orthogonal to the first horizontal direction;
removing the mask layer;
forming a plurality of sacrificial layers that fills the plurality of first trenches;
removing an upper portion of the substrate by a first thickness, such that portions of the plurality of sacrificial layers protrude from the substrate;
forming spacers on sidewalls of protruding portions of the plurality of sacrificial layers, the spacers expose portions of the substrate between adjacent sacrificial layers of the plurality of sacrificial layers;
forming a plurality of second trenches around the plurality of first trenches by etching the portions of the substrate exposed by the spacers;
forming a plurality of device isolation layers that fills the plurality of second trenches and have top surfaces positioned at a same level as a top surface of the substrate;
removing all of the plurality of sacrificial layers and the spacers;
forming a gate material layer conformally covering inner walls of the plurality of first trenches;
forming a pair of gate structures in each of the plurality of first trenches by separating the gate material layer; and
forming an epitaxial growth layer between the pair of gate structures in each of the plurality of first trenches.

17. The method of claim 16, wherein the forming of the plurality of sacrificial layers comprises:
forming a sacrificial layer material covering the top surface of the substrate and filling each of the plurality of first trenches; and
separating the sacrificial layer material into the plurality of sacrificial layers by removing an upper portion of the sacrificial layer material protruding from the top surface of the substrate.

18. The method of claim 16, wherein the forming of the plurality of device isolation layers comprises:
forming a device isolation layer material filling each of the plurality of second trenches and covering the plurality of sacrificial layers and the spacers; and
separating the device isolation layer material into the plurality of device isolation layers by removing an upper portion of the device isolation layer material protruding from the top surface of the substrate.

19. The method of claim 16, wherein each of the pair of gate structures is a buried gate structure containing a conductive material.

20. The method of claim 16, wherein each of the pair of gate structures is a vertical gate structure containing a conductive material.
